(19) United States
(12) Patent Application Publication
(10) Pub. No.: US 2016/0268226 A1
(43) Pub. Date: Sep. 15, 2016

(54) Method for Manufacturing Electronic Component

(71) Applicant: Hana Micron Inc., Asan-si (KR)

(72) Inventors: Jae-sung Lim, Suwon-si (KR); Ju-hyung Kim, Seoul (KR)

(21) Appl. No.: 15/033,700

(22) PCT Filed: Oct. 22, 2014
(86) PCT No.: PCT/KR2014/009947

§ 371 Date: May 2, 2016

(30) Foreign Application Priority Data
Oct. 30, 2013 (KR) 10-2013-0130082

(51) Int. Cl. H01L 23/00; H01L 23/373; H01L 23/498; H01L 21/683; H01L 21/78

(52) U.S. Cl. CPC H01L 24/80; H01L 21/6835; H01L 21/6836; H01L 21/78; H01L 23/4985; H01L 24/97; H01L 23/3736; H01L 2221/68327; H01L 2221/68318; H01L 2224/80203; H01L 2224/83007; H01L 2224/97

(57) ABSTRACT

A method for manufacturing an electronic component having a flexible structure includes the steps of: forming an integrated circuit element package having a foldable and expandable flexible structure, the integrated circuit element package including a first substrate having a foldable and expandable, flexible structure and having a structure on which a heat transfer part capable of transferring heat is patterned, an integrated circuit element having a foldable and expandable, flexible structure and having a first pad of which one surface is electrically connectable, and an adhesive film having a foldable and expandable, flexible structure, which is disposed between the substrate and the integrated circuit element so that the substrate and the integrated circuit element can be adhered to each other; forming a second substrate having a foldable and expandable, flexible structure and having a second pad of which one surface is electrically connectable; and performing a thermo-compression process so as to adhere the integrated circuit element package to the second substrate while electrically connecting the first pad of the integrated circuit element with the second pad of the second substrate through surface contact.

### TECHNICAL FIELD

The present invention relates to a method for manufacturing an electronic component, and more particularly, to a method for manufacturing an electronic component having a freely bendable, unfoldable, and flexible structure.

### BACKGROUND ART

Presently, an application range of an electronic industry has variously expanded. Accordingly, in a packaging technology for an integrated circuit element, such as a semiconductor memory, demands for high capacity, thinness, and compactness are increased, and in order to solve the demand, various solutions have been developed. Particularly, a bendable and flexible integrated circuit element has been recently developed, and further, a bendable and flexible integrated circuit element package including the integrated circuit element has been developed.

Further, the present applicant made the flexible integrated circuit element package, which was filed at the Korean Intellectual Property Office and was assigned with Korean Patent Application Nos. 2012-0043584 and 2012-0043577.

However, the technology for the bendable and flexible integrated circuit element package is still in a development stage, and a technology for an electronic component having a bendable or unfoldable and flexible structure mounted with the flexible integrated circuit element package is also still in the development stage.

Further, the integrated circuit element package having the flexible structure disclosed in Korean Patent Application No. 2012-0043577 is mainly manufactured by a transfer attachment, so that various research and development has been required.

### DISCLOSURE

### Technical Problem

An object of the present invention is to provide a method for manufacturing an electronic component having a flexible structure, which can be applied at a curved or bent place.

Another object of the present invention is to provide a method for manufacturing an integrated circuit element package having a bendable or foldable and flexible structure, by another method, not a transfer attachment method.

### Technical Solution

In order to achieve the aforementioned objects, an exemplary embodiment of the present invention provides a method for manufacturing an electronic component having a flexible structure, the method including: forming an integrated circuit element package having a bendable or unfoldable and flexible structure, the integrated circuit element package including a first substrate, which has a bendable or unfoldable and flexible structure and has a structure, in which a heat transfer part capable of transferring heat is patterned, an integrated circuit element, which has a bendable or unfoldable and flexible structure and one surface of which is provided with an electrically connectable first pad, and an adhesive film, which has a bendable or unfoldable and flexible structure and is provided between the substrate and the integrated circuit element so that the substrate is bonded to the integrated circuit element; forming a second substrate, which has a bendable or unfoldable and flexible structure and one surface of which is provided with an electrically connectable second pad; and performing a thermo-compression process so as to make the first pad of the integrated circuit element be in surface-contact with the second pad of the second substrate and electrically connect the first pad of the integrated circuit element and the second pad of the second substrate, and make the integrated circuit element package be in contact with the second substrate, in which heat is transferred from the first substrate to the second substrate through the heat transfer part when the thermo-compression process is performed.

The first substrate may include a polyimide (PI) film, the integrated circuit element may have a thickness of 1 to 50 μm, in which the integrated circuit element is bendable or unfoldable, and the adhesive film may include a double-sided tape or a die bonding attach film.

The heat transfer part may be formed to have a structure, in which a heat transfer material is filled inside a through-hole passing through the first substrate.

The heat transfer part may be formed to have a structure, in which a heat transfer material is buried in the first substrate.

The heat transfer part may be formed to have a straight structure or a structure, in which the heat transfer part is disposed at a predetermined interval.

The heat transfer part may include any one selected from the group consisting of copper, aluminum, and iron.

The second substrate may include glass or a flexible printed circuit board.

The thermo-compression process may be performed at a temperature of 100 to 400° C.

In order to achieve the aforementioned objects, another exemplary embodiment of the present invention provides a method for manufacturing an electronic component having a flexible structure, the method including: attaching a first carrier onto one surface of a wafer, on which a circuit pattern is formed; thinning a back surface of the wafer so that the wafer has a thickness, in which the wafer is bendable or foldable; removing the first carrier from one surface of the wafer and attaching a second carrier onto the back surface of the wafer; attaching a sawing mount onto a back surface of the second carrier that is an opposite side of one surface of the wafer; sawing the wafer up to a surface of the sawing mount so that the wafer is separated into individual dies; picking up each of the dies from the sawing mount and disposing each of the dies on a wiring substrate so that one surface of each of the dies faces one surface of the wiring substrate, which has an electric wire, has a flexible thickness, and is formed of a flexible material; and removing the second carrier from a back surface of each of the dies so that one surface of each of the dies is exposed.

The first carrier may be formed of an insulating material.

The first carrier and the sawing mount may be attached by using an ultraviolet tape, the first carrier may be removed by radiating ultraviolet rays, and the sawing up to the surface of the sawing mount may be performed by radiating ultraviolet rays.

The second carrier may be attached by using a thermal release tape, and the sawing mount and the second carrier may be removed by providing heat.

In order to achieve the aforementioned objects, yet another exemplary embodiment of the present invention provides a method for manufacturing an electronic component having a flexible structure, the method including: attaching a carrier onto one surface of a wafer, on which a circuit pattern is formed; thinning a back surface of the wafer so that the wafer has a thickness, in which the wafer is bendable or foldable; attaching a sawing mount onto the back surface of the wafer, on which the thinning is performed; sawing the wafer up to a surface of the sawing mount so that the wafer is separated into individual dies; picking up each of the dies from the sawing mount and disposing each of the dies on a wiring substrate so that a back surface of each of the dies faces one surface of the wiring substrate, which has an electric wire, has a flexible thickness, and is formed of a flexible material; removing the carrier formed on one surface of each of the dies so that one surface of each of the dies is exposed; and electrically connecting a circuit pattern of each of the dies and the electric wire of the wiring substrate.

The carrier may be formed of an insulating material.

The carrier may be attached by using a thermal release tape, and may be removed by providing heat.

The sawing mount may be attached by using an ultraviolet tape and a die attach film, and the sawing up to the surface of the sawing mount may be performed by radiating ultraviolet rays.

The circuit pattern of each of the dies and the electric wire of the wiring substrate may be electrically connected by using a wire.

### Advantageous Effects

According to the method for manufacturing the electronic component having the flexible structure of the present invention, in order to solve the problem in that when the flexible integrated circuit element package is coupled to the flexible substrate by performing thermo-compression, heat transfer is not easy due to the substrate and the adhesive film belonging to the flexible integrated circuit element package, the heat transfer part capable of transferring heat is patterned on the substrate belonging to the flexible integrated circuit element package, so that it is possible to more easily couple the flexible integrated circuit element package to the flexible substrate.

Accordingly, the method for manufacturing the electronic component having the flexible structure of the present invention may more easily solve the problem in that the flexible integrated circuit element package is not coupled to the flexible substrate well due to the heat transfer when the flexible integrated circuit element package is coupled to the flexible substrate by performing thermo-compression, so that it is recently expected to more easily manufacture an electronic component having a flexible structure.

Further, according to the method for manufacturing the electronic component having the flexible structure of the present invention, it is possible to manufacture a flexible integrated circuit element package by applying an adhesion method using a tape, not a method by a transfer attachment.

As described above, the present invention uses the adhesion using the tape, so that it is possible to manufacture a flexible integrated circuit element package even without using a transfer device, such as the method of the transfer attachment. Accordingly, the present invention may manufacture a flexible integrated circuit element package even with a simple method.

### DESCRIPTION OF DRAWINGS

FIGS. 1 to 3 are cross-sectional views schematically illustrating a method for manufacturing an electronic component having a flexible structure according to an exemplary embodiment of the present invention.

FIG. 4 is a cross-sectional view schematically illustrating an electronic component having a flexible structure obtained by the method for manufacturing the electronic component having the flexible structure of FIGS. 1 to 3.

FIG. 5 is a cross-sectional view schematically illustrating a method for manufacturing an electronic component having a flexible structure according to another exemplary embodiment of the present invention.

FIGS. 6 to 12 are cross-sectional views schematically illustrating a method for manufacturing an electronic component having a flexible structure according to another exemplary embodiment of the present invention.

FIGS. 13 to 19 are cross-sectional views schematically illustrating a method for manufacturing an electronic component having a flexible structure according to yet another exemplary embodiment of the present invention.

### BEST MODE

For the exemplary embodiments of the present invention disclosed in the text, descriptions of specific structures and functions are only provided for describing the exemplary embodiment of the present invention, and the exemplary embodiments of the present invention may be carried out in various forms, and it shall not be construed that the exemplary embodiments of the present invention are limited to the exemplary embodiments described in the text. The present invention may be variously modified and have various forms, so that specific exemplary embodiments will be illustrated in the drawings and described in detail in the text. However, this is not intended to limit the present invention to the specific disclosure form, and it should be appreciated that the present invention includes all modifications, equivalences, or substitutions included in the spirit and the technical scope of the present invention.

Terms used in the present application are used only to describe specific exemplary embodiments, and are not intended to limit the present invention. Singular expressions used herein include plural expressions unless they have definitely opposite meanings in the context. In the present application, it should be appreciated that terms “including” and “having” are intended to designate the existence of characteristics, numbers, steps, operations, constituent elements, components described in the specification or a combination thereof, and do not exclude a possibility of the existence or addition of one or more other characteristics, numbers, steps, operations, constituent elements, components, or a combination thereof in advance.

If they are not contrarily defined, all terms used herein including technological or scientific terms have the same meaning as those generally understood by a person with ordinary skill in the art. Terms which are defined in a generally used dictionary should be interpreted to have the same meaning as the meaning in the context of the related art but are not interpreted as an ideal or excessively formal meaning if it is not clearly defined in the present invention.

Hereinafter, exemplary embodiments of the present invention will be described with reference to the accompanying drawings in detail.

FIGS. 1 to 3 are cross-sectional views schematically illustrating a method for manufacturing an electronic component having a flexible structure according to an exemplary embodiment of the present invention.

Referring to FIG. 1, an integrated circuit element package 10 is formed. The integrated circuit element package 10 may include a first substrate 11, an integrated circuit element 17, and an adhesive film 15, and may have a bendable or unfoldable and flexible structure.

The first substrate 11 belongs to the integrated circuit element package 10, and may have a bendable or unfoldable and flexible structure. Accordingly, the first substrate 11 may include, for example, a polyimide film. The reason why the first substrate 11 includes the polyimide film is that the first substrate 11 needs to be firm resistant to heat applied during a thermo-compression process to be described below. That is, in the present invention, the first substrate 11 needs to be formed of a material having excellent heat resistance and a flexible material.

Further, the first substrate 11 needs to easily transfer heat. The reason is that heat needs to be easily transferred up to the second substrate during the thermo-compression process to be described below. When heat is not easily transferred up to the second substrate during the thermo-compression process to be described below, the integrated circuit element package 10 and the second substrate are not coupled.

However, since the polyimide film and the like having excellent heat resistance is selected as the first substrate 11 as described above, heat may not be easily transferred. That is, the polyimide film and the like having excellent heat resistance is weak in the heat transference.

Accordingly, in the present invention, the first substrate 11 is formed so as to have a structure, in which a heat transfer part 13 capable of transferring heat is patterned. That is, in the present invention, the first substrate 11 is formed so as to have a structure, in which the heat transfer part 13 is patterned.

Here, when the first substrate 11 is formed so as to have the structure, in which the heat transfer part 13 is patterned on the first substrate 11, a shape of the heat transfer part 13 is not limited. Accordingly, the heat transfer part 13 in the present invention may be formed to have a structure, in which a heat transfer material is filled inside a through hole passing through the first substrate 11.

Further, examples of the heat transfer material usable as the heat transfer part 13 include copper, aluminum, and iron, which may be solely used or two or more of which may be combined and used.

As described above, in the present invention, the first substrate 11 belonging to the integrated circuit element package 10 may be formed to have the flexible structure, and the heat transfer part 13 may be disposed in the first substrate 11.

Further, when the heat transfer part 13 is formed in a through-hole structure unlike the present invention, the first substrate 11 may be bent while gripping the first substrate 11 and thus a process defect may be generated. Accordingly, in the present invention, the heat transfer part 13 is formed in the structure, in which the heat transfer material is filled inside the through-hole as mentioned above.

The integrated circuit element 17 belonging to the integrated circuit element package 10 may include a semiconductor device, such as a memory device and a non-memory device, and in addition, may include an active device, a passive device, and the like.

Further, the integrated circuit element 17 is formed to have a bendable or unfoldable and flexible structure. Accordingly, the integrated circuit element 17 may include a silicon substrate having a small thickness. Particularly, the silicon substrate having a small thickness to be used for the integrated circuit element 17 may have a thickness of about several to several tens of μm. For example, a small thickness of the integrated circuit element 17, which is bendable, may be about 1.0 to 50 μm, and preferably, 5.0 to 50.0 μm. The reason is that when a thickness of the integrated circuit element 17 is less than about 1.0 μm, it is not easy to manufacture the integrated circuit element 17, and when a thickness of the integrated circuit element 17 exceeds about 50 μm, it is not easy to bend the integrated circuit element 17.

Further, the integrated circuit element 17 may include an electrically connectable first pad 19 on one surface thereof. Accordingly, the integrated circuit element 17 may have a structure of electrically connecting the integrated circuit element 17 and a second substrate to be described below or the integrated circuit element 17 and the first substrate 11 through the first pad 19.

Further, the first substrate 11 and the integrated circuit element 17 are bonded by using the adhesive film 15 so that the first substrate 11 and the integrated circuit element 17 are obtained as the integrated circuit element package 10. That is, the first substrate 11 and the integrated circuit element 17 are bonded by interposing the adhesive film 15 between the first substrate 11 and the integrated circuit element 17 so that the first substrate 11 and the integrated circuit element 17 have an integral structure.

Further, the bonding of the first substrate 11 and the integrated circuit element 17 may be performed by first bonding the adhesive film 15 to the first substrate 11, performing a transfer process using a rotating roll, and then bonding the integrated circuit element 17 bonded to the rotating roll by using the adhesive film 15 bonded to the first substrate 11.

Here, the adhesive film 15 is also formed to have a bendable or unfoldable and flexible structure. Accordingly, an example of the adhesive film 15 may include a double-sided tape or a die bonding attach film.

Further, when the integrated circuit element 17 is bonded by using the adhesive film 15, the other surface of the integrated circuit element 17 needs to be disposed to be bonded to the adhesive film 15. The reason is that the first pad 19 of the integrated circuit element 17 needs to have a structure exposed to the outside direction.

As described above, in the present invention, all of the first substrate 11, the integrated circuit element 17, and the adhesive film 15 are formed to have the bendable or unfoldable and flexible structures, so that the integrated circuit element package 10 including the first substrate 11, the integrated circuit element 17, and the adhesive film 15 may also have the bendable or unfoldable and flexible structure.

Further, in the present invention, the heat transfer part 13 is formed to be patterned on the first substrate 11, so that it is possible to create an environment, in which heat is more easily transferred during the performance of the thermo-compression process to be described below.

Further, the heat transfer part 13 is formed to be patterned on the first substrate 11, so that the heat transfer part 13 suppresses a situation, in which the first substrate 11 is bent, during the transfer process for bonding the integrated circuit element 17 to the first substrate 11, thereby decreasing the situation, in which the first substrate 11 is bent, and securing stability of the process.

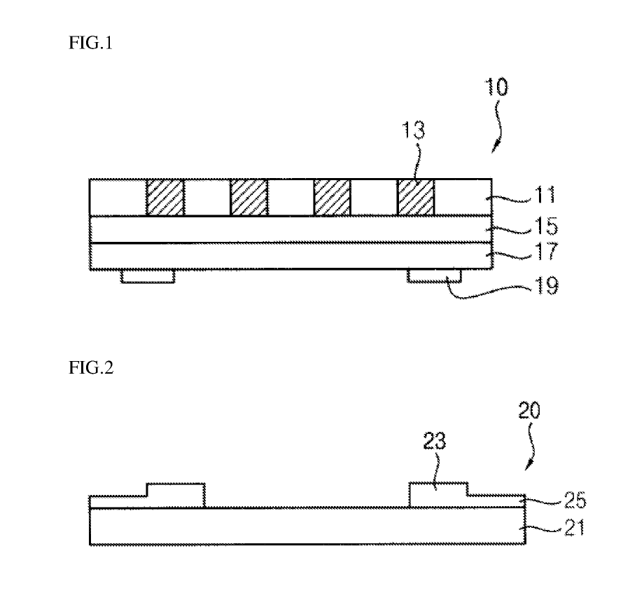

Referring to FIG. 2, a second substrate 20 is formed. Here, the second substrate 20 will be mixed and denoted with reference numerals 20 and 21.

In the present invention, the second substrate 21 also has a bendable or unfoldable structure. Accordingly, the second substrate 21 may include a glass or a flexible printed circuit board having a small thickness.

Here, when the second substrate 21 is glass, it may be understood that the electronic component of the present invention including the second substrate 21 is a display device, and when the second substrate 21 is a flexible printed circuit board, it may be understood that the electronic component including the second substrate 21 is a bendable or unfoldable memory card and the like.

Further, when the second substrate 21 is glass, it may be understood that the thermo-compression process to be described below is a Chip On Glass (COG) process, and when the second substrate 21 is a flexible printed circuit board, it may be understood that the thermo-compression process to be described below is a Chip On Flexible PCB (COF) process.

Further, the second substrate 21 may include an electrically connectable second pad 23 on one surface thereof. That is, in the present invention, the second substrate 21, which has the bendable or unfoldable structure and includes the electrically connectable second pad 23 on one surface thereof, is formed. In this case, the second pad 23 may be formed to have a structure connected with an electric wire 25.

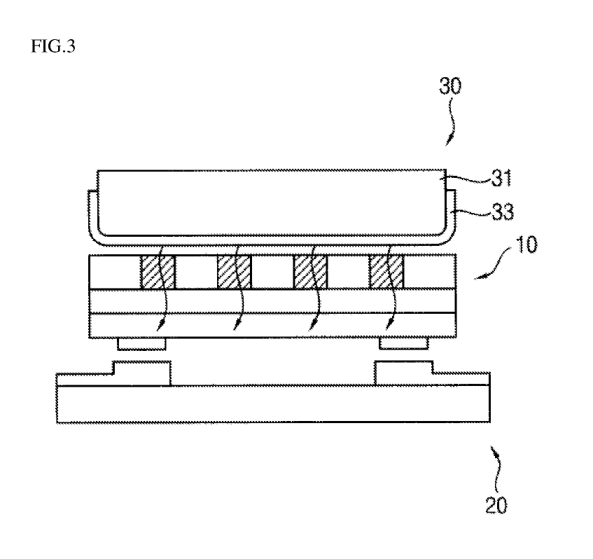

Referring to FIG. 3, the integrated circuit element package 10 having the flexible structure illustrated in FIG. 1 is coupled with the second substrate 20 having the flexible structure illustrated in FIG. 2. That is, the electronic component is formed by coupling the integrated circuit element package 10 and the second substrate 20 so that the integrated circuit element package 10 and the second substrate 20 have an integral structure. Here, when the second substrate 20 is glass, it may be understood that the electronic component obtained by coupling the integrated circuit element package 10 and the second substrate 20 so that the integrated circuit element package 10 and the second substrate 20 have the integral structure is a display device and the like having a bendable or unfoldable and flexible structure, and when the second substrate 20 is a flexible printed circuit board, it may be understood that the electronic component obtained by coupling the integrated circuit element package 10 and the second substrate 20 so that the integrated circuit element package 10 and the second substrate 20 have the integral structure is a memory card and the like having a bendable or unfoldable and flexible structure.

The coupling of the integrated circuit element package 10 and the second substrate 20 may be mainly performed by the thermo-compression process. In this case, the first pad 19 of the integrated circuit element 17 included in the integrated circuit element package 10 and the second pad 23 of the second substrate 20 need to be electrically connected with each other. Accordingly, the thermo-compression process for coupling the integrated circuit element package 10 and the second substrate 20 may be performed in a state where the first pad 19 of the integrated circuit element 17 is in surface-contact with the second pad 23 of the second substrate 20.

The thermo-compression process may be mainly achieved by using a thermo-compression device 30 including a bonding head 31 and a cushion material 33. Accordingly, the thermo-compression process may be performed in a state where the thermo-compression device is disposed on the first substrate 11 of the integrated circuit element package 10.

Accordingly, in the thermo-compression process, only when heat is easily transferred to the second substrate 20 through the first substrate 11 of the integrated circuit element package 10, the integrated circuit element package 10 and the second substrate 20 may be more easily coupled.

Accordingly, the present invention has the structure, in which the heat transfer part 13 is patterned in the first substrate 11, so that heat is more easily transferred to the second substrate 20 through the first substrate 11 by the heat transfer part 13 during the thermo-compression process, and as a result, it is possible to more easily couple the integrated circuit element package 10 and the second substrate 20.

When the heat transfer part 13 is not formed in the first substrate 11, heat is not easily transferred from the first substrate 11 to the second substrate 20 during the thermo-compression process of the first substrate 11 and the adhesive film 15 under the first substrate 11, so that the integrated circuit element package 10 is not coupled with the second substrate 20 well. Accordingly, in the present invention, the heat transfer part 13 is formed in the first substrate 11 as mentioned above, so that heat is sufficiently transferred from the first substrate 11 to the second substrate 20 through the heat transfer part 13 during the thermo-compression process, and as a result, it is possible to more easily couple the integrated circuit element package 10 and the second substrate 20.

Further, when a thermo-compression temperature during the performance of the thermo-compression process is lower than about 100° C., the thermo-compression temperature is slightly low, so that there may be a problem in that the integrated circuit element package 10 is not easily coupled with the second substrate 20, and when a thermo-compression temperature is higher than about 400° C., there may be a problem in that the integrated circuit element package 10 and the second substrate 20 have serious thermal stress and the like. Accordingly, in the present invention, a thermo-compression temperature during the thermo-compression process may be adjusted to be about 100° C. to 400° C.

As described above, in the present invention, it is possible to more easily couple the integrated circuit element package 10 and the second substrate 20 so that the integrated circuit element package 10 and the second substrate 20 have the integral structure by performing the thermo-compression process. As mentioned above, heat may be easily transferred by the heat transfer part 13 which is formed in the first substrate 11 to have the patterned structure, so that the integrated circuit element package 10 and the second substrate 20 may be easily coupled to each other.

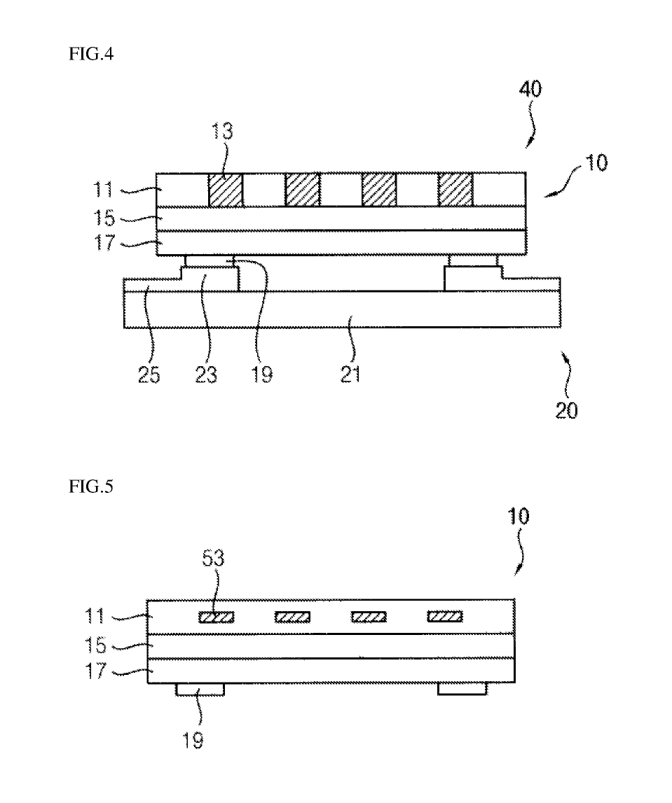

Referring to FIG. 4, an electronic component 40 in the present invention is obtained by coupling the integrated circuit element package 10 illustrated in FIG. 1 and the second substrate 20 illustrated in FIG. 2 so that the integrated circuit element package 10 and the second substrate 20 have the integral structure by performing the thermo-compression process illustrated in FIG. 3. That is, the electronic component 40 may be formed to have an integral structure by bonding the integrated circuit element package 10 and the second substrate 20 by performing the thermo-compression process.

Here, the heat transfer part 13 formed in the first substrate 11 easily transfers heat during the thermo-compression process as mentioned above, thereby enabling the integrated circuit element package 10 and the second substrate 20 to be easily coupled, and when the heat transfer part 13 is included in the electronic component 40 as illustrated in FIG. 4, the heat transfer part 13 may also serve to discharge heat of the electronic component 40. That is, the heat transfer part 13 may serve to transfer heat during the thermo-compression process for forming the electronic component 40, and may serve to discharge heat when being included in the electronic component 40.

As described above, in the present invention, the integrated circuit element package 10 has the bendable or unfoldable and flexible structure and the second substrate 20 has the bendable or unfoldable and flexible structure, so that it is possible to obtain the electronic component 40 having the entirely bendable or unfoldable and flexible structure. Particularly, the electronic component 40 has the bendable or unfoldable and flexible structure and is formed with the heat transfer part 13, so that the heat transfer part 13 serves to transfer heat during the thermo-compression process, thereby more easily coupling the integrated circuit element package 10 and the second substrate 20 so that the integrated circuit element package 10 and the second substrate 20 have the integral structure, and the heat transfer part 13 serves to discharge heat when obtaining the electronic component 40, thereby minimizing thermal stress of the electronic component 40.

Accordingly, in the method for manufacturing the electronic component 40 having the flexible structure of the present invention, it is possible to more easily couple the integrated circuit element package 10 to the second substrate 20 by patterning the heat transfer part 13, which is capable of transferring heat, to the first substrate 11 belonging to the integrated circuit element package 10. Accordingly, the method for manufacturing the electronic component 40 having the flexible structure of the present invention may more easily solve the problem in that the integrated circuit element package 10 is not coupled with the second substrate 20 well due to the heat transference when the integrated circuit element package 10 and the second substrate 20 are coupled by performing the thermo-compression, so that recently, it is possible to more easily manufacture the electronic component 40 having the flexible structure.

FIG. 5 is a cross-sectional view schematically illustrating a method for manufacturing an electronic component having a flexible structure according to another exemplary embodiment of the present invention.

In FIG. 5, the integrated circuit element package 10 has the same structure as that of the integrated circuit element package 10 in FIG. 1, except for a structure of a heat transfer part 53, so that the same component is denoted by the same reference numeral, and a detailed description thereof will be omitted.

Referring to FIG. 5, the heat transfer part 53 may be formed to have a structure buried in the first substrate 11. That is, the heat transfer part 53 may be formed to have a structure, in which a heat transfer material is buried in the first substrate 11.

Here, the heat transfer part 53 is formed to have the structure buried in the first substrate 11 in order to prevent a defect during the process, such as an overhang generable at an entrance of the through-hole or void generable due to a failure of sufficiently filling the through-hole with the heat transfer material when the heat transfer material is filled in the through hole in FIG. 1.

Accordingly, in the present invention, the heat transfer part 53 may also be formed to have the structure buried in the first substrate 11.

Further, the heat transfer part 53 formed to have the structure buried in the first substrate 11 may also be formed to have a straight structure in a horizontal direction of the first substrate 11 or a structure, in which the heat transfer part 53 is disposed at a predetermined interval.

As mentioned above, in the present invention, the heat transfer part 53 may also be formed to have various structures.

FIGS. 6 to 12 are cross-sectional views schematically illustrating a method for manufacturing an electronic component having a flexible structure according to another exemplary embodiment of the present invention.

Referring to FIG. 6, a first carrier 150 is bonded to one surface of a wafer 110, on which a circuit pattern is formed.

Here, the manufacturing process using the wafer 110, on which the circuit pattern is formed, may be performed at a wafer level, a flexible integrated element package obtained from each wafer 110, on which the circuit pattern is formed, may include a semiconductor device, such as a memory device and a non-memory device, an active device, and a passive device, and bumps 130, which are electrically connected with the circuit pattern, may be formed on one surface of the wafer 110.

Further, the first carrier 150 is attached for easily handling the wafer 110, on which the circuit pattern is formed, and the first carrier 150 needs to be prevented from applying electric impact to the circuit pattern formed on one surface of the wafer 110, so that the first carrier 150 may be formed of an insulating material.

Further, the first carrier 150 may be attached onto one surface of the wafer 110 by mainly using an ultraviolet tape 160. The reason is that the first carrier 150 is removed by radiating ultraviolet rays which will be described below.

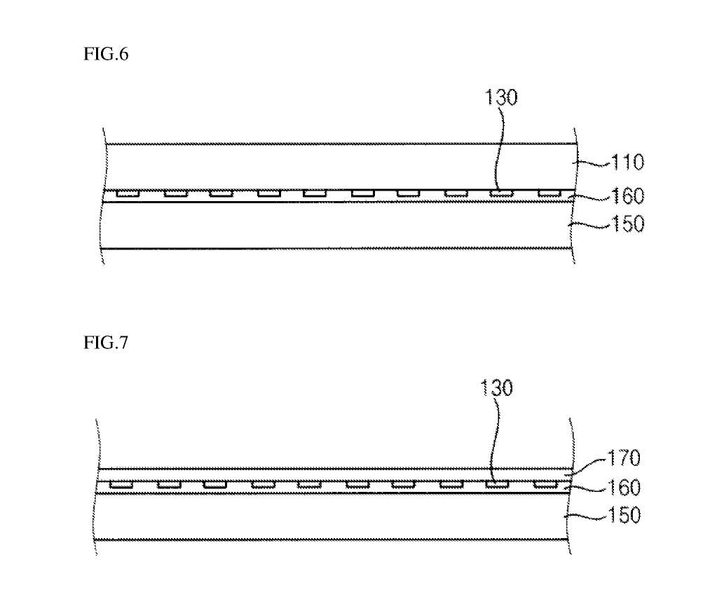

Referring to FIG. 7, a back surface of the wafer 110 is thinned. In this case, the back surface of the wafer 110 may be thinned by mainly performing grinding.

Here, the thinning of the back surface of the wafer 110 may be performed to a range of a thickness, in which the wafer 110 is bendable or foldable, and when the back surface of the wafer 110 is thinned to have a thickness of less than about 1 μm, a process error range is too small and it is not easy to control the process, so that the thickness of less than about 1 μm is not preferable, and when the back surface of the wafer 110 is thinned to have a thickness of more than about 50 μm, it is impossible to obtain the wafer 170 having the bendable or foldable and flexible structure, so that the thickness of more than about 50 μm is not preferable.

Accordingly, in the present invention, the back surface of the wafer 110 of FIG. 6 is thinned to have a thickness of about 1 to 50 μm as illustrated in FIG. 7. Accordingly, it is possible to obtain a wafer 170 (hereinafter, referred to as a “flexible wafer”) having the bendable or foldable and flexible structure by thinning the back surface of the wafer 110.

Referring to FIG. 8, the first carrier 150 is removed from one surface of the flexible wafer 170, and a second carrier 210 is attached onto a back surface of the flexible wafer 170. Here, the order of the removal of the first carrier 110 and the attachment of the second carrier 210 may be changed.

The first carrier 110 may be removed by radiating ultraviolet rays to one surface of the flexible wafer 170, to which the first carrier 110 is attached. The first carrier 110 is attached by using the ultraviolet tape 160 as mentioned above, so that it is possible to remove the first carrier 110 by radiating ultraviolet rays.

Further, the second carrier 210 is attached to the back surface of the flexible wafer 170, and the second carrier 210 may be attached by mainly using a thermal release tape 220. The reason is that the second carrier 210 is removed by providing heat which will be described below. Further, the second carrier 210 is attached for easily handling the flexible wafer 170, and the second carrier 210 is attached to the back surface of the flexible wafer 170, so that a material of the second carrier 210 may not be limited.

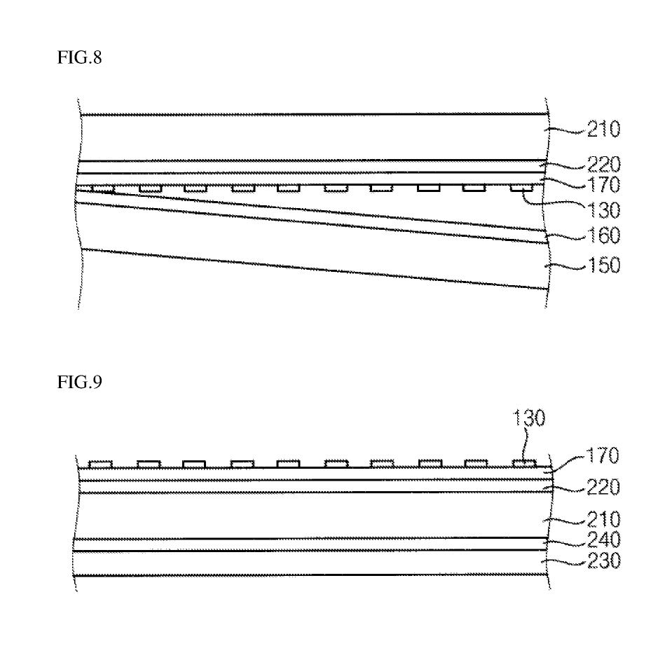

Referring to FIG. 9, a sawing mount 230 is attached onto a back surface of the second carrier 210. That is, the sawing mount 230 is attached to the back surface of the second carrier 210 opposite to one surface of the flexible wafer 170. Accordingly, the sawing mount 230, the second carrier 210, and the flexible wafer 170 may be sequentially stacked. In this case, one surface of the flexible wafer 170, on which the circuit pattern is formed, may be exposed.

Here, the sawing mount 230 is a member attached for supporting each individual die when performing a sawing process for separating a structure at a wafer level to be described below into the individual dies.

Further, the sawing mount 230 may be attached by using an ultraviolet tape 240 in order to remove the ultraviolet tape 240, which is partially exposed, by radiating ultraviolet rays after performing the sawing process for separating the flexible wafer 170 into the individual dies which will be described below. That is, the sawing process needs to be performed up to a surface of the sawing mount 230 in order to remove even the ultraviolet tape 240 used for attaching the sawing mount 230.

Further, as mentioned above, since the second carrier 210 is attached by the thermal release tape 220, the ultraviolet tape 240 is used when the sawing mount 230 is attached. That is, when the thermal release tape 220 is used when the sawing mount 230 is attached, heat is provided in the sawing process, and in this case, the surface of the sawing mount 230 may be exposed, but the second carrier 210 may be removed, so that the sawing mount 230 is attached by using the ultraviolet tape 240 as mentioned above.

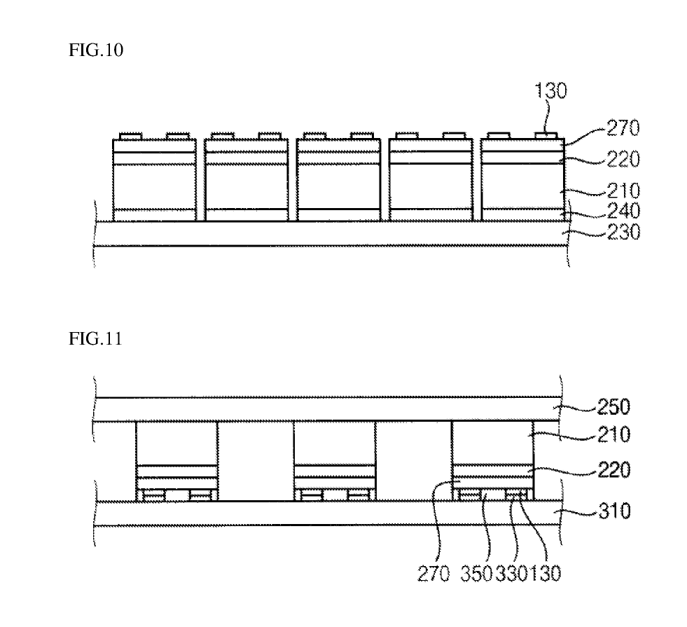

Referring to FIG. 10, the sawing is performed up to the surface of the sawing mount 230 so that the flexible wafer 170 at the wafer level is separated into the individual dies 270.

That is, in FIGS. 6 to 9, the process is performed at the wafer level, so that the flexible wafer 170 is separated into the individual dies 270 by performing the sawing process as illustrated in FIG. 10.

Here, the sawing process uses a member, such as a diamond wheel, and the radiation of the ultraviolet rays, and the flexible wafer 470 may be separated into the individual dies 270 by sawing the flexible wafer 470 by using the member, such as the diamond wheel, and then removing the partially exposed ultraviolet tape 240 by radiating ultraviolet rays.

Accordingly, in the present invention, the sawing process is performed so that up to the surface of the sawing mount 230 is exposed, and the flexible wafer 170 at the wafer level may be separated into the individual dies 270 by performing the sawing process.

Referring to FIG. 11, a wiring substrate 310 which includes an electric wire, has a flexible thickness, and is formed of a flexible material, is attached onto one surface of the flexible wafer 170, that is, each of the individual dies 270, on which the sawing is performed.

Here, the wiring substrate 310 is formed of a bendable or foldable and flexible material with a flexible thickness, and may mainly include a flexible printed circuit board.

Further, the wiring substrate 310 and the circuit pattern in each of the individual dies 270 need to be electrically connected. Accordingly, in the present invention, the wiring substrate 310 is attached to one surface of each of the individual dies 270 as mentioned above so that each connection terminal 330 of the wiring substrate 310 is in surface-contact with a bump 130 of each of the individual dies 270.

That is, each of the individual dies 270 is picked up from the sawing mount 230 and is disposed on the wiring substrate 310 so that one surface of each of the individual dies 270 faces one surface of the wiring substrate 310. Here, the pick-up of each individual die 270 from the sawing mount 230 is performed in a state where adhesive force of the ultraviolet tape 240 is weak by radiating ultraviolet rays, so that it is possible to easily pick up each individual die 270.

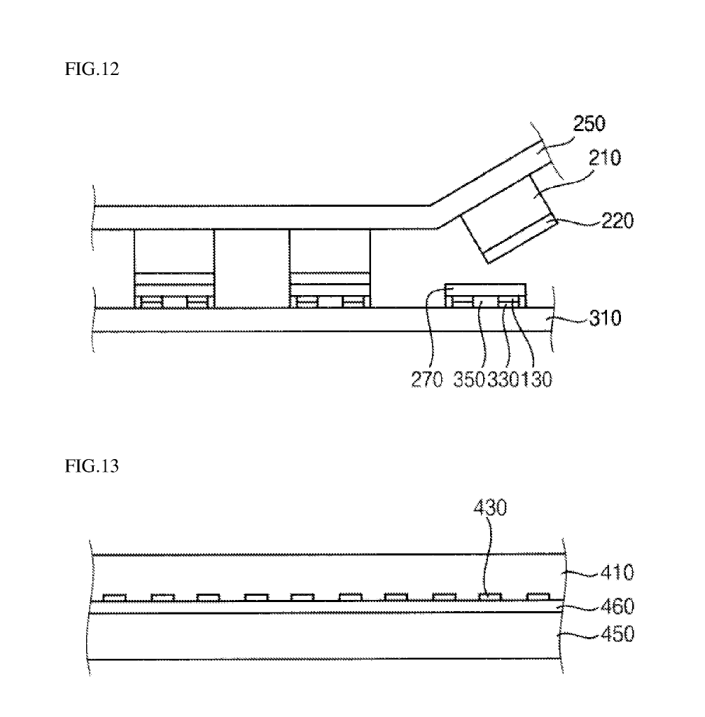

Referring to FIG. 12, the second carrier 210 is removed from a back surface of each of the individual dies 270, which are the wafers on which the sawing is performed.

Particularly, the second carrier 210 is a removal target when the second carrier 210 is removed, so that it is possible to remove the second carrier 210 by providing heat. That is, as mentioned above, the second carrier 210 is attached by the thermal release tape 220, so that it is possible to remove the second carrier 210 by weakening adhesive force of the thermal release tape 220 by providing heat as mentioned above.

Further, in the present invention, since the second carriers 210 are separated from each other by the sawing process, it is possible to remove the second carriers 210 by using a removing tape 250 in a lump. That is, it is possible to remove the second carriers 210 in a lump by attaching the removing tape 250 to all of the second carriers, which are separated from each other, and then weakening adhesive force of the thermal release tape 220 by providing heat as described above.

Accordingly, in the present invention, it is possible to obtain an integrated circuit element package, that is, the electronic component, in which each of the individual dies 270 is attached onto the wiring substrate 310, by sequentially performing the processes of FIGS. 6 to 12. Particularly, since the wiring substrate 310 and each of the individual dies 270 have the bendable or foldable and flexible structure, in the present invention, it is possible to obtain the electronic component having a flexible structure that is the flexible integrated circuit element package, in which each of the individual dies 270 is attached onto the wiring substrate 310.

As described above, in the present invention, it is possible to obtain the electronic component having the flexible structure through an adhesion control using the ultraviolet tapes 160 and 240 and the thermal release tape 220, so that the use of the transfer device in the transfer attachment may be omitted.

FIGS. 13 to 19 are cross-sectional views schematically illustrating a method for manufacturing an electronic component having a flexible structure according to yet another exemplary embodiment of the present invention.

Referring to FIG. 13, carriers 450 are attached onto one surface of a wafer 410, on which a circuit pattern is formed.

Here, the manufacturing process using the wafer 410, on which the circuit pattern is formed, may be performed at a wafer level, a flexible integrated element package obtained from each wafer 410, on which the circuit pattern is formed, may include a semiconductor device, such as a memory device and a non-memory device, an active device, and a passive device, and bumps 430, which are electrically connected with the circuit pattern, may be formed on one surface of the wafer 410.

Further, the carrier 450 is attached for easily handling the wafer 410, on which the circuit pattern is formed, and the carrier 450 needs to be prevented from applying electric impact to the circuit pattern formed on one surface of the wafer 410, so that the carrier 450 may be formed of an insulating material.

Further, the carrier 450 may be attached onto one surface of the wafer 410 by mainly using a thermal release tape 460. The reason is that the carrier 410 is removed by providing heat which will be described below.

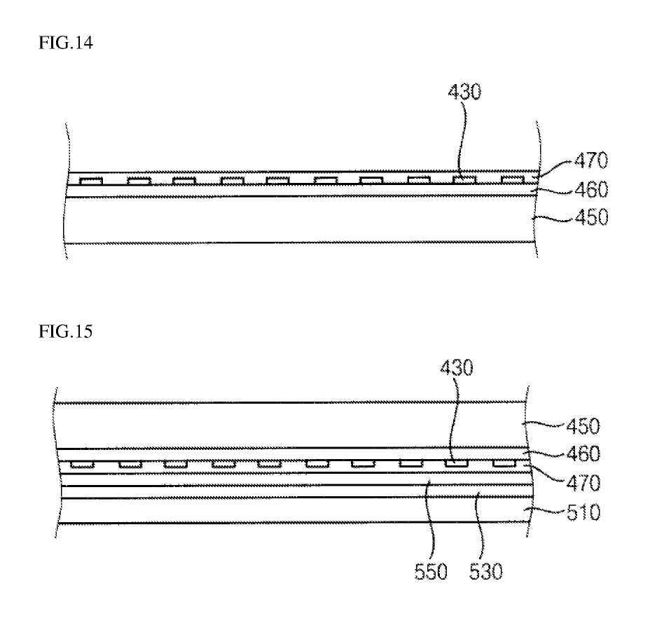

Referring to FIG. 14, a back surface of the wafer 410 is thinned. In this case, the back surface of the wafer 410 may be thinned by mainly performing grinding.

Here, the thinning of the back surface of the wafer 410 may be performed to a range of a thickness, in which the wafer 410 is bendable or foldable, and when the back surface of the wafer 410 is thinned to have a thickness of less than about 1 μm, a process error range is too small and it is not easy to control the process, so that the thickness of less than about 1 μm is not preferable, and when the back surface of the wafer 410 is thinned to have a thickness of more than about 50 μm, it is impossible to obtain the wafer 470 having the bendable or foldable and flexible structure, so that the thickness of more than about 50 μm is not preferable.

Accordingly, in the present invention, the back surface of the wafer 410 of FIG. 13 is thinned to have a thickness of about 1 to 50 μm as illustrated in FIG. 14. Accordingly, it is possible to obtain a wafer 470 having the bendable or foldable and flexible structure by thinning the back surface of the wafer 410.

Referring to FIG. 15, a sawing mount 510 is attached onto a back surface of the flexible wafer 470 second carrier 210, on which the thinning is performed. Accordingly, the sawing mount 510, the flexible wafer 470, and the carrier 450 may be sequentially stacked. In this case, one surface of the flexible wafer 470, on which the circuit pattern is formed, may be positioned between the sawing mount 510 and the carrier 450.

Here, the sawing mount 510 is a member attached for supporting each individual die when performing a sawing process for separating a structure at a wafer level to be described below into the individual dies.

Here, the sawing mount 510 may be attached by using an ultraviolet tape 530 and a Die Attach Film (DAF) 550. In this case, the ultraviolet tape 530 is attached so as to face the sawing mount 510, and the DAF 550 is attached to face one surface of the flexible wafer 470.

Here, the sawing mount 510 may be attached by using the ultraviolet tape 530 in order to remove the ultraviolet tape 530, which is partially exposed, by radiating ultraviolet rays after the performance of the sawing process for separating the flexible wafer 470 into individual dies, which will be described below. That is, the sawing process needs to be performed up to a surface of the sawing mount 510 in order to remove even the ultraviolet tape 530 used for attaching the sawing mount 510.

Further, as mentioned above, since the carrier 450 is attached by the thermal release tape 460, the ultraviolet tape 530 is used when the sawing mount 510 is attached. That is, when the thermal release tape 460 is used when the sawing mount 510 is attached, heat is provided in the sawing process, and in this case, the surface of the sawing mount 510 may be exposed, but the carrier 450 may be removed, so that the sawing mount 510 is attached by using the ultraviolet tape 530 as mentioned above.

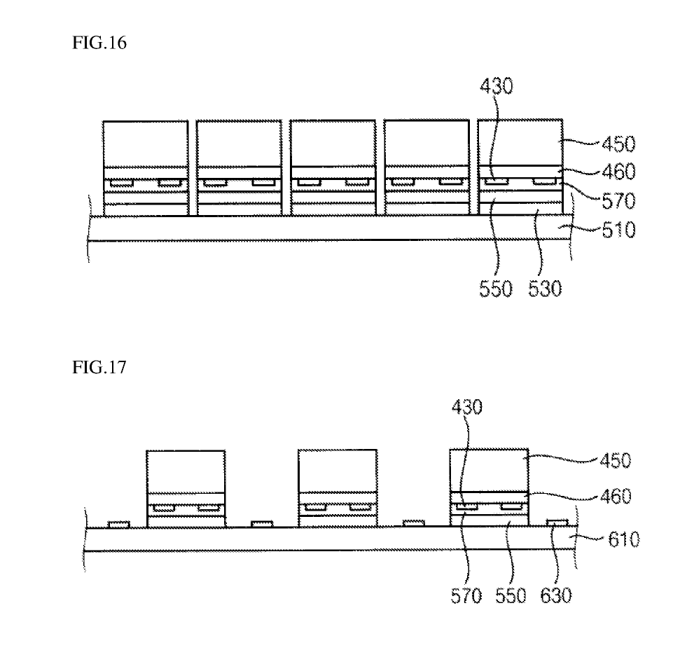

Referring to FIG. 16, the sawing is performed up to the surface of the sawing mount 510 so that the flexible wafer 470 at the wafer level is separated into the individual dies 570. That is, in FIGS. 13 to 15, the process is performed at the wafer level, so that the flexible wafer 470 is separated into the individual dies 570 by performing the sawing process as illustrated in FIG. 16.

Here, the sawing process uses a member, such as a diamond wheel, and the radiation of the ultraviolet rays, and the flexible wafer 470 may be separated into the individual dies 270 by sawing the flexible wafer 170 by using the member, such as the diamond wheel, and then removing the partially exposed ultraviolet tape 530 by radiating ultraviolet rays.

Accordingly, in the present invention, the sawing process is performed up to the surface of the sawing mount 510, and the flexible wafer 470 at the wafer level may be separated into the individual dies 570 by performing the sawing process.

Referring to FIG. 17, each of the individual dies 570 obtained by sawing the flexible wafer 470 is picked up and is disposed on a wiring substrate 610.

Here, the wiring substrate 610 is formed of a bendable or foldable and flexible material with a flexible thickness, and may mainly include a flexible printed circuit board.

Further, each of the individual dies 570 may be disposed so that a back surface of each of the individual dies 570 faces one surface of the wiring substrate 610. Accordingly, each of the individual dies 570 is disposed so that the back surface of each of the individual dies 570 faces one surface of the wiring substrate 610, so that the carrier 450 may be exposed.

Further, each of the individual dies 570 may be attached to the wiring substrate 610 by using the DAF 550. That is, each of the individual dies 570 may be attached to the wiring substrate 610 by preparing the DAF 550 in advance as illustrated in FIG. 15.

Referring to FIG. 18, the carrier 450 attached onto one surface of each of the individual dies 570 is removed so that one surface of each of the individual dies 570 is exposed.

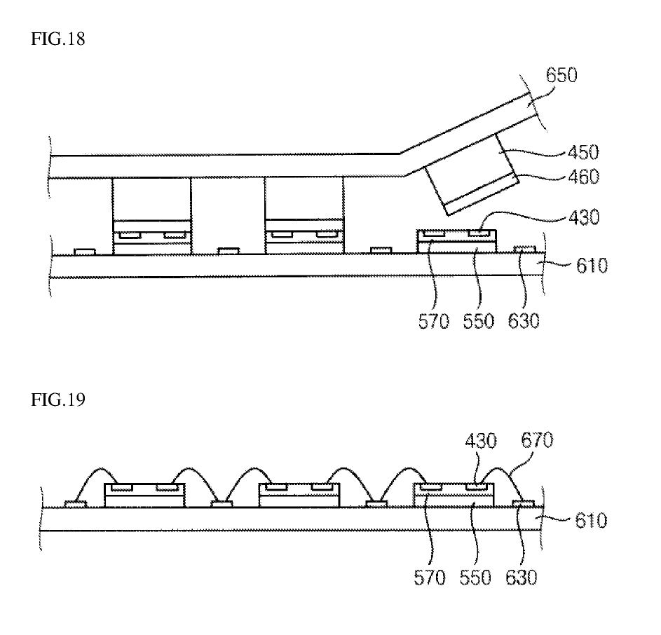

Here, the carrier 450 may be removed by attaching a removing tape 650 to the carrier 450 having the exposed structure, and then weakening adhesive force of the thermal release tape 460 used for attaching the carrier 450 by providing heat. That is, the carrier 450 may be removed together by removing the removing tape 650 in a state where adhesive force of the thermal release tape 460 is weakened through the application of heat. Referring to FIG. 19, the circuit pattern of each of the individual dies 570 and the wiring substrate 610 are electrically connected.

Here, the electric connection of the circuit pattern of each of the individual dies 570 and the wiring substrate 610 is to connect the bump 430 formed on each of the individual dies 570 and a connection terminal 630 formed on the wiring substrate 610, and electrically connect the bump 430 and the connection terminal 630 by mainly using a wire 670.

Accordingly, in the present invention, it is possible to obtain an integrated circuit element package, that is, an electronic component, in which each of the individual dies 570 is attached onto the wiring substrate 610, by sequentially performing the processes of FIGS. 13 to 19. Particularly, since the wiring substrate 610 and each of the individual dies 570 have the bendable or foldable and flexible structure, in the present invention, it is possible to obtain the electronic component having a flexible structure that is the flexible integrated circuit element package, in which each of the individual dies 570 is attached onto the wiring substrate 610.

As described above, in the present invention, it is possible to obtain the flexible integrated circuit element package through an adhesion control using the ultraviolet tape 530 and the thermal release tape 460, so that the use of the transfer device in the transfer attachment may be omitted.

Although the present invention has been described with reference to the exemplary embodiments, those skilled in the art may understand that the present invention may be variously modified and changed without departing from the spirit and the scope of the present invention described in the accompanying claims.<Explanation of Reference Numerals and Symbols>

| | |
|---|---|
| 10: Integrated circuit element package | 11: First substrate |
| 13, 53: Heat transfer part | 15: Adhesive film |
| 17: Integrated circuit element | 19: First pad |
| 20, 21: Second substrate | 23: Second pad |
| 25: Electric wire | 30: Thermo-compression |
| | device |
| 31: Bonding head | 33: Cushion material |
| 40: Electronic component | 110, 410: Wafer |
| 130, 430: Bump | 160, 240, 530: Ultraviolet tape |
| 150, 210, 450: Carrier | 170, 470: Flexible wafer |
| 220, 460: Thermal release tape | 230, 510: Sawing mount |
| 250, 650: Removing tape | 270, 570: Individual die |
| 310, 610: Wiring substrate | 330, 630: Connection terminal |
| 350: Epoxy resin | 550: Die attach film |
| 670: Wire | |

1. A method for manufacturing an electronic component having a flexible structure, the method comprising:
forming an integrated circuit element package having a bendable or unfoldable and flexible structure, the integrated circuit element package including a first substrate, which has a bendable or unfoldable and flexible structure and has a structure, in which a heat transfer part capable of transferring heat is patterned, an integrated circuit element, which has a bendable or unfoldable and flexible structure and one surface of which is provided with an electrically connectable first pad, and an adhesive film, which has a bendable or unfoldable and flexible structure and is provided between the substrate and the integrated circuit element so that the substrate is bonded to the integrated circuit element;
forming a second substrate, which has a bendable or unfoldable and flexible structure and one surface of which is provided with an electrically connectable second pad; and
performing a thermo-compression process so as to make the first pad of the integrated circuit element be in surface-contact with the second pad of the second substrate and electrically connect the first pad of the integrated circuit element and the second pad of the second substrate, and make the integrated circuit element package be in contact with the second substrate, in which heat is transferred from the first substrate to the second substrate through the heat transfer part when the thermo-compression process is performed,
wherein the first substrate includes a polyimide (PI) film, the integrated circuit element has a thickness of 1 to 50 μm, in which the integrated circuit element is bendable or unfoldable, and the adhesive film includes a double-sided tape or a die bonding attach film.

2. The method of claim 1, wherein the heat transfer part is formed to have a structure, in which a heat transfer material is filled inside a through-hole passing through the first substrate.

3. The method of claim 1, wherein the heat transfer part is formed to have a structure, in which a heat transfer material is buried in the first substrate.

4. The method of claim 3, wherein the heat transfer part is formed to have a straight structure or a structure, in which the heat transfer part is disposed at a predetermined interval.

5. The method of claim 1, wherein the heat transfer part includes any one selected from the group consisting of copper, aluminum, and iron.

6. The method of claim 1, wherein the second substrate includes glass or a flexible printed circuit board.

7. A method for manufacturing an electronic component, the method comprising:
attaching a first carrier onto one surface of a wafer, on which a circuit pattern is formed;
thinning a back surface of the wafer so that the wafer has a thickness, in which the wafer is bendable or foldable;
removing the first carrier from one surface of the wafer and attaching a second carrier onto the back surface of the wafer;
attaching a sawing mount onto a back surface of the second carrier that is an opposite side of one surface of the wafer;
sawing the wafer up to a surface of the sawing mount so that the wafer is separated into individual dies;
picking up each of the dies from the sawing mount and disposing each of the dies on a wiring substrate so that one surface of each of the dies faces one surface of the wiring substrate, which has an electric wire, has a flexible thickness, and is formed of a flexible material; and
removing the second carrier from a back surface of each of the dies so that one surface of each of the dies is exposed.

8. The method of claim 7, wherein the first carrier is formed of an insulating material.

9. The method of claim 7, wherein the first carrier and the sawing mount are attached by using an ultraviolet tape, the first carrier is removed by radiating ultraviolet rays, and the sawing up to the surface of the sawing mount is performed by radiating ultraviolet rays.

10. The method of claim 7, wherein the second carrier is attached by using a thermal release tape, and is removed by providing heat.

11. A method for manufacturing an electronic component, the method comprising:
attaching a carrier onto one surface of a wafer, on which a circuit pattern is formed;
thinning a back surface of the wafer so that the wafer has a thickness, in which the wafer is bendable or foldable;
attaching a sawing mount onto the back surface of the wafer, on which the thinning is performed;
sawing the wafer up to a surface of the sawing mount so that the wafer is separated into individual dies;
picking up each of the dies from the sawing mount and disposing each of the dies on a wiring substrate so that a back surface of each of the dies faces one surface of the wiring substrate, which has an electric wire, has a flexible thickness, and is formed of a flexible material;
removing the carrier formed on one surface of each of the dies so that one surface of each of the dies is exposed; and
electrically connecting a circuit pattern of each of the dies and the electric wire of the wiring substrate.

12. The method of claim 11, wherein the carrier is formed of an insulating material.

13. The method of claim 11, wherein the carrier is attached by using a thermal release tape, and is removed by providing heat.

14. The method of claim 11, wherein the sawing mount is attached by using an ultraviolet tape and a die attach film, and the sawing up to the surface of the sawing mount is performed by radiating ultraviolet rays.

15. The method of claim 11, wherein the circuit pattern of each of the dies and the electric wire of the wiring substrate are electrically connected by using a wire.
